(19) United States
(12) Patent Application Publication
(10) Pub. No.: US 2023/0203695 A1
(43) Pub. Date: Jun. 29, 2023

(54) Alkaline Composition For Copper Electroplating Comprising A Defect Reduction Agent

(71) Applicant: BASF SE, Ludwigshafen am Rhein (DE)

(72) Inventors: Charlotte Emnet, Ludwigshafen (DE); Lucas Benjamin Henderson, Ludwigshafen (DE); Alexander Fluegel, Ludwigshafen (DE); Sathana Kitayaporn, Hillsboro, NJ (US); Nadine Engelhardt, Ludwigshafen (DE)

(21) Appl. No.: 17/565,059

(22) Filed: Dec. 29, 2021

(51) Int. Cl. C25D 3/38; C25D 7/12; C25D 5/02; H01L 21/768

(52) U.S. Cl. CPC C25D 3/38; C25D 7/123; C25D 5/02; H01L 21/76873; H01L 21/76879; H01L 23/53228

(57) ABSTRACT

Described herein is a composition for depositing copper on a semiconductor substrate, the composition including

(a) copper ions;
(b) an additive of formula S1

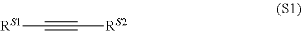

(c) a complexing agent; and
(d) optionally a buffer or base capable of adjusting the pH to a pH of from 7 to 13;
where the variables are as defined herein; and
where the pH of the composition is from 7 to 13 and where the composition is free of any cyanide.

The present invention relates to an alkaline composition for depositing a copper layer onto a semiconductor substrate, its use and a deposition process by using such composition.

### BACKGROUND OF THE INVENTION

Filling of small features, such as vias and trenches, by metal electroplating is an essential part of the semiconductor manufacture process. It is well known, that the presence of organic substances as additives in the electroplating bath can be crucial in achieving a uniform metal deposit on a substrate surface and in avoiding defects, such as voids and seams, within the metal lines.

Void-free bottom-up filling of submicrometer-sized interconnect features by using acidic copper electroplating baths on a copper seed is well known in the art.

With further decreasing aperture size of the features like vias or trenches to dimensions of below 5 nanometers and even below 3 nanometers, respectively, the filling of the interconnects with copper becomes especially challenging, also since the copper seed deposition prior to the copper electrodeposition might exhibit inhomogeneity and non-conformity and thus further decreases the aperture sizes particularly at the top of the apertures. The smaller the size of the feature and the higher the aspect ratio of the feature become the more difficult it is to get a continuous seed on the side walls of the feature without significant seed overhang.

To avoid these difficulties a non-copper seed such as cobalt or ruthenium was proposed in WO 2019/199614 A1. An acidic electroplating solution for plating copper on a non-copper liner layer includes a low copper concentration, acidic pH, organic additives, and bromide ions as a copper complexing agent. Also unpublished international patent application No. PCT/EP2021/068001 discloses an acidic bromide containing copper electroplating bath.

However, cobalt is a less noble metal compared to copper and quickly corrodes in the presence of an acid and oxygen, particularly if copper is present, too. On the other hand, alkaline electroplating baths that would show less cobalt corrosion provide bad filling and dirty copper fillings due to the use of complexings agents that are required to keep copper in solution.

Also alkaline compositions for copper electroplating copper on a copper or other metal seeds are generally known in the art. For example, WO 2015/086180 discloses a copper electroplating bath comprising copper ions and a promoter of nucleation of metallic copper on said substrate, characterized in that the promoter of nucleation of copper is a combination of 2,2′-bipyridine, imidazole and an electrochemically inert cation selected from the group consisting of cesium (Cs²⁺), alkylammonium and mixtures thereof to improve the nucleation of copper on the most resistive materials that are a barrier to the diffusion of copper such as ruthenium or cobalt.

There is still a need for a copper electroplating composition that allows a void-free deposition of copper in small recessed features, such as vias or trenches, of semiconductor substrates.

It is therefore an object of the present invention to provide an electroplating composition that is capable of providing a substantially void-free filling of features on the nanometer and/or on the micrometer scale with copper on a non-copper metal seed, particularly a cobalt seed. It is also an object of the present invention to provide an electroplating composition that is capable of depositing a homogeneous, smooth and void-free copper seed layer on a non-copper metal seed, particularly a cobalt seed. For resistivity reasons, this seed layer needs to have a low impurity level.

For resistivity reasons, it is also beneficial that the copper layer deposited on the cobalt seed layer exhibits a low resistivity. A low resistivity of the copper deposit is supported by a low impurity level in the deposited copper film which means that little C, N, S, O, H, Cl, P or other elements than copper are incorporated in the copper film during the copper electrodeposition.

### SUMMARY OF THE INVENTION

The present invention provides a copper electroplating bath that may generally be used in two ways:
1. With the bath a copper seed layer is deposited onto the semiconductor substrate to allow using a state-of-the art acidic copper on copper electroplating bath to fill the respective recessed features; and
2. With the bath a direct void-free filling, ideally a bottom-up filling, of the recessed features may also be achieved.

Therefore the present invention provides a composition for depositing copper on a semiconductor substrate, the composition comprising
(a) copper ions;
(b) an additive of formula S1

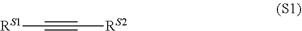

(c) a complexing agent; and
(d) optionally a buffer or a base capable of adjusting the pH to a pH of from 7 to 13;
   wherein
R^{S1} is selected from —X^{S}—Y^{S}—;
R^{S2} is selected from R^{S1} and R^{S3};
X^{S} is selected from linear or branched C₁ to C₁₀ alkanediyl, linear or branched C₂ to C₁₀ alkenediyl, linear or branched C₂ to C₁₀ alkynediyl, and —X^{S6}—(O—C₂H₃R^{S6})—;
Y^{S} is selected from OR^{S3}, NR^{S3}R^{S4}, N+R^{S3}R^{S4}R^{S5} and NH—(C═O)—R^{S3};
R^{S3}, R^{S4}, R^{S5} are the same or different and are selected from (i) H, (ii) C₅ to C₂₀ aryl, (iii) C₁ to C₁₀ alkyl (iv) C₆ to C₂₀ arylalkyl, (v) C₆ to C₂₀ alkylaryl, which may be substituted by OH, SO₃H, COOH or a combination thereof, and (vi) —(C₂H₃R^{S6}—O)ₙ—R^{S6}, and wherein R^{S3} and R^{S4} may together form a ring system, which may be interrupted by O or NR^{S7};
X^{S6} is C₁ to C₆ alkanediyl;
m, n are integers independently selected from 1 to 30;
R^{S6} is selected from H and C₁ to C₅ alkyl;
R^{S7} is selected from R^{S6} and

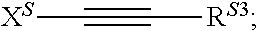

and
wherein the pH of the composition is from 7 to 13 and wherein the composition is free of any cyanide.

The invention further relates to the use of a metal plating bath comprising a composition as defined herein for depositing copper on substrates comprising recessed features having an aperture size of 50 nanometers or less, 15 nm or less, 10 nm or less or even 5 nm or less essentially without forming voids, preferably by bottom.up fill.

The invention further relates to a process for depositing copper on a semiconductor substrate comprising a recessed feature having an aperture size of 50 nm or less, preferably 15 nm or less, the recessed feature comprising a metal seed, the process comprising
(a) bringing a composition as described herein into contact with the metal seed,
(b) applying a current for a time sufficient to deposit a continuous seed of copper onto the surface of the recessed feature or to completely fill the recessed feature with copper.

The alkaline copper electroplating composition according to the invention provides a substantially void-free filling of features on the nanometer and/or on the micrometer scale with copper on a non-copper metal seed, particularly a cobalt seed. It also allows depositing a homogenous, smooth and void-free seed layer on a non-copper metal seed, particularly a cobalt seed. A further advantage of the present invention is that the deposited copper, e.g. a completely filled recessed feature or a continuous seed, has a much lower impurity level.

### BRIEF DESCRIPTION OF THE FIGURES

FIG. 1 shows a FIB/SEM inspected wafer that was used for electrodepositing copper in comparative example 2c, and examples 2d, 2e, and 3e;

FIG. 2 shows a FIB/SEM inspected wafer that was used for electrodepositing copper in comparative examples 3c and example 3d;

FIG. 3 shows a FIB/SEM inspected wafer that was electroplated with copper according to comparative example 2a;

FIG. 4 shows a FIB/SEM inspected wafer that was electroplated with copper according to example 2b;

FIG. 5 shows a FIB/SEM inspected wafer that was electroplated with copper according to comparative example 2c;

FIG. 6 shows a FIB/SEM inspected wafer that was electroplated with copper according to example 2d;

FIG. 7 shows a FIB/SEM inspected wafer that was electroplated with copper according to example 2e;

FIG. 8 shows a FIB/SEM inspected wafer that was electroplated with copper according to example 3a;

FIG. 9 shows a FIB/SEM inspected wafer that was electroplated with copper according to example 3b;

FIG. 10 shows a FIB/SEM inspected wafer that was electroplated with copper according to comparative example 3c;

FIG. 11 shows a FIB/SEM inspected wafer that was electroplated with copper according to example 3d;

FIG. 12 shows a FIB/SEM inspected wafer that was electroplated with copper according to example 3e;

### DETAILED DESCRIPTION OF THE INVENTION

The compositions according to the inventions comprise copper ions, and an additive of formula S1 as described below (also referred to herein as “defect reducing agent”).

### Defect Reducing Agent

It has been found that the additives of formula S1

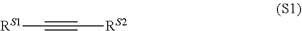

are particularly useful additives for alkaline electroplating of copper on semiconductor substrates, particularly those comprising submicrometer-sized recessed features, most particularly those having aperture sizes having nanometer or micrometer scale, preferably aperture sizes having 50 nanometers or less, 15 nm or less, 10 nm or less or even 5 nm or less.

SIMS measurements of copper films plated with a defect reducing agent in the plating bath exhibit that the amount of C, N, S, O, H, Cl, P or other elements than copper incorporated in the copper film during the copper electrodeposition is smaller than in copper films plated without defect reducing agent in the plating bath.

In the addives of formula S1, R^{S1} is selected from X^{S}—Y^{S}, wherein X^{S} is a divalent spacer group selected from linear or branched C₁ to C₁₀ alkanediyl, linear or branched C₂ to C₁₀ alkenediyl, linear or branched C₂ to C₁₀ alkynediyl, and —X^{S6}—(O—C₂H₃R^{S6})ₘ—. m is an integer selected from 1 to 30, preferably from 1 to 15, even more preferably from 1 to 10, most preferably from 1 to 5. The spacer X^{S6} is C₁ to C₆ alkanediyl, preferably methanediyl, ethandiyl, propanediyl or butanediyl, most preferably methanediyl or ethandiyl.

In a first preferred embodiment X^{S} is selected from linear or branched C₁ to C₆ alkanediyl, preferably from C₁ to C₄ alkanediyl.

In a second preferred embodiment X^{S} is selected from methanediyl, ethane-1,1-diyl and ethane-1,2-diyl. In a third preferred embodiment X^{S} is selected from propan-1,1-diyl, butane-1,1-diyl, pentane-1,1-diyl, and hexane-1,1-diyl. In a fourth preferred embodiment X^{S} is selected from propane-2-2-diyl, butane-2,2-diyl, pentane-2,2-diyl, and hexane-2,2-diyl.

In a fifth preferred embodiment X^{S} is selected from propane-1-2-diyl, butane-1,2-diyl, pentane-1,2-diyl, and hexane-1,2-diyl. In a sixth preferred embodiment X^{S} is selected from propane-1-3-diyl, butane-1,3-diyl, pentane-1,3-diyl, and hexane-1,3-diyl.

Y^{S} is a monovalent group and may be selected from OR^{S3}, with R^{S3} being selected from (i) H, (ii) C₅ to C₂₀ aryl, preferably C₅, C₆, and C₁₀ aryl, (iii) C₁ to C₁₀ alkyl, preferably C₁ to C₆ alkyl, most preferably C₁ to C₄ alkyl (iv) C₆ to C₂₀ arylalkyl, preferably C₆ to C₁₀ arylalkyl, (v) C₆ to C₂₀ alkylaryl, all of which may be substituted by OH, SO₃H, COOH or a combination thereof, and (vi) —(C₂H₃R^{S6}—O)ₙ—R^{S6}. In a preferred embodiment, R^{S3} may be C₁ to C₆ alkyl or H. R^{S6} may independently be selected from H and C₁ to C₅ alkyl, preferably from H and C₁ to C₄ alkyl, most preferably H, methyl or ethyl.

As used herein, aryl comprises carbocyclic aromatic groups as well as heterocyclic aromatic groups in which one or more carbon atoms are exchanged by one or more N or O atoms. As used herein, arylalkyl means an alkyl group substituted with one or more aryl groups, such as but not limited to benzyl and methylpyridine. As used herein, alkylaryl means an aryl group substituted with one or more alkyl groups, such as but not limited to toluyl.

In another preferred embodiment, R^{S3} is selected from H to form a hydroxy group. In another preferred embodiment, R^{S3} is selected from polyoxyalkylene groups of formula —(C₂H₃R^{S6}—O)ₙ—R^{S6}. R^{S6} is selected from H and C₁ to C₅ alkyl, preferably from H and C₁ to C₄ alkyl, most preferably from H, methyl or ethyl. Generally, n may be an integer from 1 to 30, preferably from 1 to 15, most preferably from 1 to 10. In a particular embodiment polyoxymethylene, polyoxypropylene or a poly(oxymethylene-co-oxypropylene) may be used. In another preferred embodiment, R^{S3} may be selected from C₁ to C₁₀ alkyl, preferably from C₁ to C₆ alkyl, most preferably methyl and ethyl.

Furthermore, Y^{S} may be an amine group NR^{S3}R^{S4}, wherein R^{S3} and R^{S4} are the same or different and may have the meanings of R^{S3} described for OR^{S3} above.

In a preferred embodiment, R^{S3} and R^{S4} are selected from H to form an NH₂ group. In another preferred embodiment, at least one of R^{S3} and R^{S4}, preferably both are selected from polyoxyalkylene groups of formula —(C₂H₃R^{S6}—O)ₙ—R^{S6}. R^{S6} is independently selected from H and C₁ to C₅ alkyl, preferably from H and C₁ to C₄ alkyl, most preferably H, methyl or ethyl. In yet another preferred embodiment, at least one of R^{S3} and R^{S4}, preferably both are selected from C₁ to C₁₀ alkyl, preferably from C₁ to C₆ alkyl, most preferably methyl and ethyl.

R^{S3} and R^{S4} may also together form a ring system, which may be interrupted by O or NR^{S7}. R^{S7} may be selected from R^{S6} and

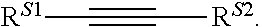

Preferably the ring system is formed by two substituents R^{S3} and R^{S4} which are bound to the same N atom. Such ring system may preferably comprise 4 or 5 carbon atoms to form a 5 or 6 membered carbocyclic system. In such carbocyclic system one or two of the carbon atoms may be substituted by oxygen atoms.

Furthermore, Y^{S} may be a positively charged ammonium group N+R^{S3}R^{S4}R^{S5}, R^{S3}, R^{S4}, R^{S5} are the same or different and may have the meanings of R^{S3} described for OR^{S3} and NR^{S3}R^{S4} above. In a preferred embodiment R^{S3}, R^{S4} and R^{S}S are independently selected from H, methyl or ethyl. In one embodiment at least one of R^{S3}, R^{S4} and R^{S}S, preferably two, most preferably all, are selected from polyoxyalkylene groups of formula —(C₂H₃R^{S6}—O)ₙ—R^{S6}.

m may be an integer selected from 1 to 30, preferably from 1 to 15, even more preferably from 1 to 10, most preferably from 1 to 5.

In the additives of formula S1 R^{S2} may be either R^{S1} or R^{S3} as described above. If R^{S2} is R^{S1}, R^{S1} may be selected to form a symmetric compound (both R^{S1}s are the same) or an asymmetric compound (the two R^{S1}s are different).

In a preferred embodiment R^{S2} is H.

Particularly preferred aminoalkynes are those in which
(a) R^{S1} is X^{S}—NR^{S3}R^{S4} and R^{S2} is H;
(b) R^{S1} is X^{S}—NR^{S3}R^{S4} and R^{S2} is X^{S}— NR^{S3}R^{S4} with X^{S} being selected from linear C₁ to C₄ alkanediyl and branched C₃ to C₆ alkanediyl;

Particularly preferred hydroxyalkynes or alkoxyalkynes are those in which
(a) R^{S1} is X^{S}—OR^{S3} and R^{S2} is H;
(b) R^{S1} is X^{S}—OR^{S3} and R^{S2} is X^{S}—OR^{S3} with X^{S} being selected from linear C₁ to C₄ alkanediyl and branched C₃ to C₆ alkanediyl;

Particularly preferred alkynes comprising an amino and a hydroxy group are those in which R^{S1} is X^{S}—OR^{S3}, particularly X^{S}—OH, and R^{S2} is X^{S}—NR^{S3}R^{S4} with X^{S} being independently selected from linear C₁ to C₄ alkanediyl and branched C₃ to C₆ alkanediyl;

The amine groups in the additives may be selected from primary (R^{S3}, R^{S4} is H), secondary (R^{S3} or R^{S4} is H) and tertiary amine groups (R^{S3} and R^{S4} are both not H).

The alkynes may comprise one or more terminal triple bonds or one or more non-terminal triple bonds (alkyne functionalities). Preferably, the alkynes comprise one or more terminal triple bonds, particularly from 1 to 3 triple bonds, most preferably one terminal triple bond.

Particularly preferred specific primary aminoalkynes are:

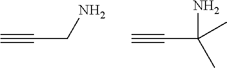

Particularly preferred specific secondary aminoalkynes are:

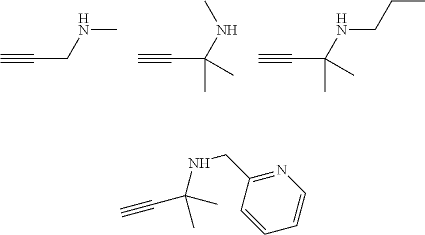

Particularly preferred specific tertiary aminoalkynes are:

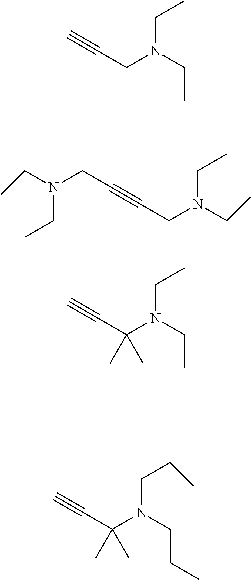

Other preferred additives are those in which the rests R^{S3} and R^{S4} may together form a ring system, which is optionally interrupted by O or NR^{S3}. Preferably, the rests R^{S3} and R^{S4} together form a C₅ or C bivalent group in which one or two, preferably one, carbon atoms may be exchanged by O or NR^{S7}, with R^{S7} being selected from hydrogen, methyl or ethyl.

An example of such compounds is:

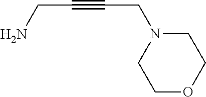 [SMILES: NCC#CCN1CCOCC1]

It may be received by reaction of propargyl amine with formaldehyde and morpholine.

Another preferred additive comprising a saturated heterocyclic system is:

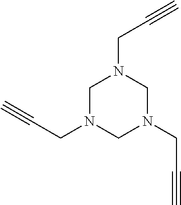

In this case R^{S3} and R^{S4} together form a ring system which is interrupted by two NR^{S3} groups, in which R^{S3} is selected from CH₂—C═C—H. This additive comprises three terminal triple bonds.

The amino groups in the additives may further be quaternized by reaction with alkylating agents such as but not limited to dialkyl sulphates like DMS, DES or DPS, benzyl chloride or chlormethylpyridine. Particularly preferred quaternized additives are:

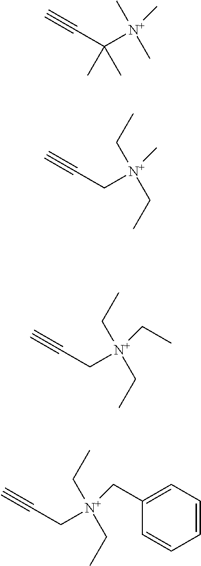

Particularly preferred specific pure hydroxyalkynes are:

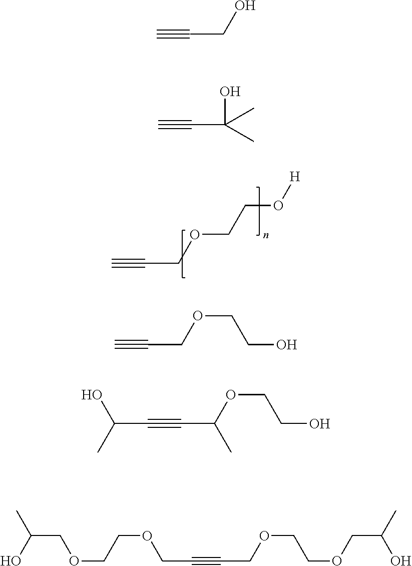

Particularly preferred specific aminoalkynes comprising OH groups are:

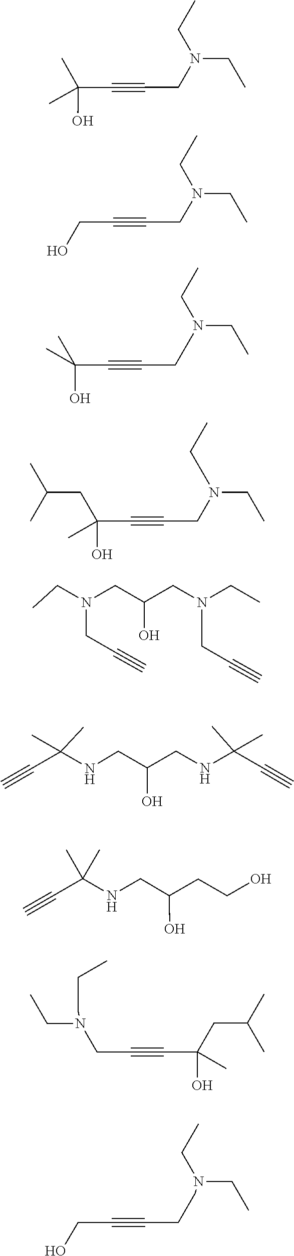

Also in this case the rests R^{S3} and R^{S4} may together form a ring system, which is optionally interrupted by O or NR^{S3}. Preferably, the rests R^{S3} and R^{S4} together form a C₅ or C₆ bivalent group in which one or two, preferably one, carbon atoms may be exchanged by O or NR^{S7}, with R^{S7} being selected from hydrogen, methyl or ethyl.

Examples for such compounds are:

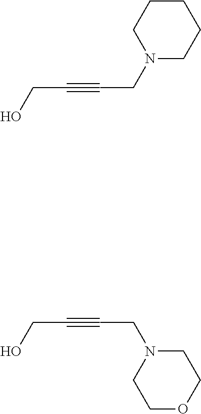 [SMILES: OCC#CCN1CCCCC1 ; OCC#CCN1CCOCC1]

These may be received by reaction of propargyl alcohol with formaldehyde and piperidine or morpholine, respectively.

By partial reaction with alkylating agents mixtures of additives may be formed. In one embodiment, such mixtures may be received by reaction of 1 mole diethylaminopropyne and 0.5 mole epichlorohydrin, 1 mole diethylaminopropyne and 0.5 mole benzylchloride, 1 mole diethylaminopropyne with 0.9 mole dimethyl sulphate, 1 mole dimethyl propyne amine and 0.33 mole dimethyl sulphate, or 1 mole dimethyl propyne amine and 0.66 mole dimethyl sulphate. In another embodiment such mixtures may be received by reaction of 1 mole dimethyl propyne amine and 1.5, 1.9, or 2.85 mole dimethyl sulphate, 1 mole dimethyl propyne amine and 0.5 mole epichlorohydrin, 1 mole dimethyl propyne amine and 2.85 diethyl sulphate, or 1 mole dimethyl propyne amine and 1.9 mole dipropyl sulphate.

In a further embodiment, the additives may be substituted by SO₃H (sulfonate) groups or COOH (carboxy) groups. Specific sulfonated additives may be but are not limited to butynoxy ethane sulfonic acid, propynoxy ethane sulfonic acid, 1,4-di-(p-sulfoethoxy)-2-butyne, 3-(p-sulfoethoxy)-propyne.

In one embodiment a single additive according to the invention may be used in the copper electroplating baths. In another embodiment two or more of the additives are used in combination.

In general, the defect reducing agents of the invention are preferably used in an amount of about 0.1 ppm to about 30000 ppm, based on the total weight of the plating bath. Particularly suitable amounts of defect reducing agent useful in the present invention are 1 to 10000 ppm, and more particularly 10 to 1000 ppm. Also other amounts may be used if needed.

### Complexing Agent

The copper electroplating composition also comprises a complexing agent to keep the copper ions in solution and to avoid its precipitation.

The complexing agent may particularly be selected from polyamines, aminocarboxylic acids, aminophosphonic acids, aminoalcohols, polyalcohols, hydroxycarboxylic acids, hydroxyphosphonic acids, thioureas, and polycarboxylic acids.

Without limitation, useful polymines are methylenediamine, ethylenediamine, tetramethylenediamine, pentamethylenediamine, hexamethylenediamine, diethylenetriamine, tetraethylenepentamine, pentaethylenehexamine, or hexaethyleneheptamine, or combinations thereof.

Without limitation, useful amino carboxylic acids are ethylenediaminetetraacetic acid (EDTA), hydroxyethylethylenediaminetriacetic acid (HEDTA), diethylenetriaminepentaacetic acid (DTPA), triethylenetetraaminehexaacetic acid (TTHA), ethylenediaminetetrapropionic acid, nitrilotriacetic acid (NTA), iminodiacetic acid (IDA), Iminodipropionic acid (IDP), metaphenylenediaminetetraacetic acid, 1,2-diaminocyclohexane-N,N, N′, N′-tetraacetic acid, diaminopropionic acid, combinations thereof, or salts thereof

Without limitation, useful amino alcohols are monoethanolamine, diethanolamine, triethanolamine, monopropanolamine; Dipropanolamine, tripropanolamine, or combinations thereof.

Without limitation, useful hydroxycarboxylic acids are tartaric acid, citric acid, malic acid, gluconic acid, glycolic acid, lactic acid, glucoheptonic acid, combinations thereof, or salts thereof.

Without limitation, useful hydroxyphosphonic acids are 1-Hydroxyethylidene-1,1-diphosphonic acid (etidronic acid), combinations thereof, or salts thereof.

Thioureas are thiourea and thiourea derivatives.

Without limitation, a useful polyalcohol is sorbitol.

Preferred complexing agents are hydroxycarboxylic acids such as but not limited to citric acid, tartaric acid and hydroxyphosphonic acids such as but not limited to etidronic acid.

The complexing agent may be used alone or in any combination, and the content of the complexing agent in the plating bath is usually from 0.01 to 2 mol/1, preferably from 0.1 to 0.6 mol/1.

Buffer/base The composition optionally comprises a buffer or a base (also referred to as “pH adjustor”) that is capable of adjusting the pH to a pH of from 7 to 13.

Without limitation, typical bases are metal, preferably alkaline or alkaline earth metal hydroxides, carbonates, NH₄OH, alkyl ammonium hydroxides, and the like.

Preferred bases are NaOH, KOH, and combinations thereof.

The alkylammonium ions may for example be compounds of formula (N—R^{B1}R^{B2}R^{B3}R^{B4})⁺ in which R^{B1}; R^{B2}; R^{B3}; and R^{B4} independently selected from H and a C₁-C₄ alkyl, provided that at least one of R^{B}1; R^{B2}; R^{B3}; and R^{B4} is a C₁-C₄ alkyl.

A C₁-C₄ alkyl may be for example methyl, ethyl, n-propyl or n-butyl. Preferred alkylammonium ions are tetra-alkylammonium, for example tetramethylammonium, tetraethylammonium, tetrapropyl-ammonium or tetrabutylammonium, methyltriethylammonium and ethyltrimethylammonium.

The cations are supplied in the form of salts, for example a sulfate salt. The counter-ion of the cation in the salt is preferably the same counter-ion than the counter-ion of the copper(II) salt.

### Grain Refiner

The copper electroplating composition may optionally comprise a grain refiner.

Preferred grain refiners are those of formula G1

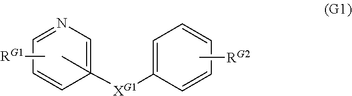

or salts thereof,
wherein
R^{G1} is selected from one or more H, C₁ to C₄ carboxyl, C₁ to C₄ alkyl, C₁ to C₆ alkoxy, halogen, and CN;
R^{G2} is selected from one or more H, C₁ to C₄ carboxyl, C₁ to C₄ alkyl, C₁ to C₆ alkoxy, halogen, and CN; and
X^{G1} is selected from C₁ to C₆ alkanediyl or a group —X^{G11}—C(O)—O—X^{G12}—;
X^{G11} is selected from a chemical bond or C₁ to C₄ alkandiyl;
X^{G12} is selected from a chemical bond or C₁ to C₄ alkandiyl; and
   wherein R^{G1} or R^{G2}, comprises at least one C₁ to C₄ carboxyl group, or group X^{G1} is —X^{G11}—C(O)—O—)—X^{G12}—.

In a first preferred embodiment the grain refiner is a compound of formula G1 or salts thereof, wherein
R^{G1} is selected from one or more H, C₁ to C₄ carboxyl, C₁ to C₄ alkyl, C₁ to C₆ alkoxy, halogen, and CN;
R^{G2} is selected from one or more H, C₁ to C₄ carboxyl, C₁ to C₄ alkyl, C₁ to C₆ alkoxy, halogen, H and CN; and
X^{G1} is a C₁ to C₄ alkanediyl;
   and wherein R^{G1} or R^{G2} comprises at least one C₁ to C₄ carboxyl group.

Particularly preferred grain refiners of the first embodiment are those of formula G2a or G2b or salts thereof

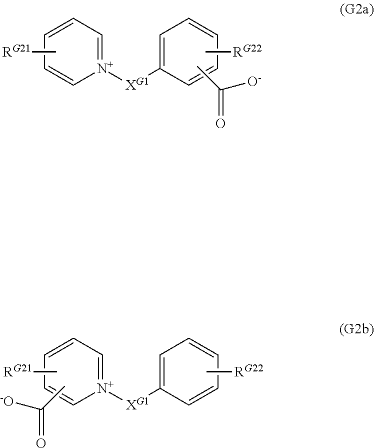

wherein
R^{G21} is selected from one or more H, C₁ to C₃ alkyl, C₁ to C₄ alkoxy, halogen, and CN;
R^{G22} is selected from one or more H, C₁ to C₄ alkyl, C₁ to C₆ alkoxy, halogen, and CN; and
X^{G1} is methandiyl, ethanediyl, propanediyl or butanediyl.

A particularly preferred grain refiner of formula G2b is 3-carboxy-1-penylmethylpyridinium (inner salt).

In a second preferred embodiment the grain refiner is a compound of formula G1 or salts thereof, wherein
R^{G1} is selected from one or more H, C₁ to C₄ carboxyl, C₁ to C₄ alkyl, C₁ to C₆ alkoxy, halogen, and CN;
R^{G2} is selected from one or more H, C₁ to C₄ carboxyl, C₁ to C₄ alkyl, C₁ to C₆ alkoxy, halogen, and CN; and
X^{G1} is a group —X^{G11}—C(O)—O—)—X^{G12}_
X^{G11} X^{G12} are independently selected from C₁ to C₄ alkandiyl.

Particularly preferred grain refiners of the second embodiment are those of formula G3a, G3b, G3c, or salts thereof

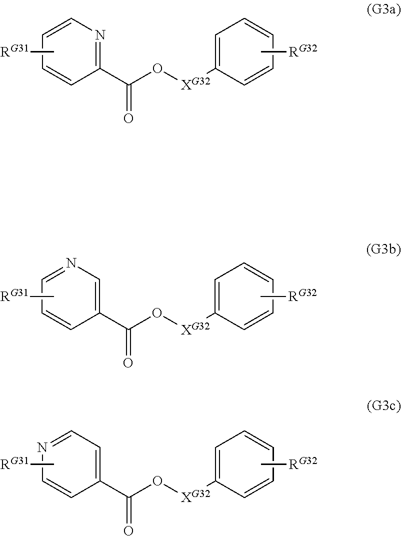

wherein
R^{G3}1 is selected from one or more H, C₁ to C₄ carboxyl, C₁ to C₄ alkyl, C₁ to C₆ alkoxy, halogen, and CN;
R^{G32} is selected from one or more H, C₁ to C₄ carboxyl, C₁ to C₄ alkyl, C₁ to C₆ alkoxy, C₁ to C carboxy, halogen, and CN; and
X^{G32} is selected from a chemical bond or C₁ to C₄ alkandiyl.

Particularly preferred grain refiners of formula G3b are 4-(Methoxycarbonyl)benzyl pyridine-3-carboxylate and benzyl pyridine-3-carboxylate.

In general, the total amount of the grain refiners in the electroplating bath is from 0.5 ppm to 10000 ppm based on the total weight of the plating bath. The additives according to the present invention are typically used in a total amount of from about 0.1 ppm to about 1000 ppm based on the total weight of the plating bath and more typically from 1 to 100 ppm, although greater or lesser amounts may be used.

SIMS measurements of copper films plated with a grain refiner in the plating bath exhibit that the amount of C, N, S, O, H, Cl, P or other elements than copper incorporated in the copper film during the copper electrodeposition is smaller than in copper films plated without grain refiner in the plating bath.

### Other Additives

A large variety of further additives may typically be used in the bath to provide desired surface finishes for the copper plated metal. Usually more than one additive is used with each additive forming a desired function. Advantageously, the electroplating baths may contain one or more of wetting agents or surfactants like Lutensol®, Plurafac® or Pluronic® (available from BASF) to get rid of trapped air or hydrogen bubbles and the like. Further components to be added are stress reducers, levelers and mixtures thereof.

In a further embodiment, surfactants may be present in the electroplating composition in order to improve wetting. Wetting agents may be selected from nonionic surfactants, anionic surfactants and cationic surfactants.

In a preferred embodiment non-ionic surfactants are used. Typical non-ionic surfactants are fluorinated surfactants, polyglycols, or poly oxyethylene and/or oxypropylene containing molecules.

### Electrolyte

A wide variety of metal plating baths may be used with the present invention. Metal electroplating baths typically comprise or essentially consist of a copper ion source, an electrolyte, the defect reducing agent, a complexing agent, optionally a grain refiner, optionally a base or a buffer, and optionally further additives as described herein.

The plating baths are typically aqueous. The term “aqueous” means that the plating bath is water based. The water may be present in a wide range of amounts. Any type of water may be used, such as distilled, deionized or tap. Preferably the plating bath is a solution of the compounds described herein in water. Preferably the water is electronic grade deionized water. Other solvents besides water may be present in minor amounts but preferably water is the only solvent.

The metal ion source may be any compound capable of releasing copper ions to be deposited in the electroplating bath in sufficient amount, i.e. is at least partially soluble in the electroplating bath.

In a preferred embodiment, no further metals besides copper are present in the electroplating bath. In other preferred embodiment the metal comprises copper and comprise tin in amount of below 0.1 g/l, preferably below 0.01 g/l, most preferably no tin. Most preferably there is no other metal than copper present in the composition.

In a preferred embodiment, the electroplating composition does not comprise any reducing agents that reduces the copper ions to metallic copper.

It is preferred that the copper ion source is soluble in the plating bath to release 100% of the metal ions. Suitable copper ion sources are metal salts and include, but are not limited to, metal sulfates, metal halides, metal acetates, metal nitrates, metal fluoroborates, metal alkylsulfonates, metal arylsulfonates, metal sulfamates, metal gluconates and the like. It is preferred that the metal is copper. It is further preferred that the source of copper ions is copper sulfate, copper chloride, copper acetate, copper citrate, copper nitrate, copper fluoroborate, copper methane sulfonate, copper phenyl sulfonate and copper p-toluene sulfonate. Copper sulfate pentahydrate and copper methane sulfonate are particularly preferred. Such metal salts are generally commercially available and may be used without further purification.

The copper ion source may be used in the present invention in any amount that provides sufficient metal ions for electroplating on a substrate.

Copper is typically present in an amount in the range of from about 0.2 to about 300 g/l of the plating solution. Generally, the defect reducing agent is useful in low copper, medium copper and high copper baths. Low copper means a copper concentration from about 0.3 to about 20 g/l.

The pH of the electroplating composition is in the range of from about 7 to about 13, preferably from about 8 to about 13, more preferably from about 8 to about 12, most preferably from about 9 to about 11.

The electroplating composition is free of any cyanide ions.

In a preferred embodiment the composition is essentially free of chloride ions. Essentially free from chloride means that the chloride content is below 1 ppm, particularly below 0.1 ppm.

### Process

According to one embodiment of the present invention an alkaline copper electroplating bath comprising a composition as described herein may be used for depositing copper on substrates comprising recessed features having an aperture size of 50 nanometers or less, which features preferably comprise a seed of cobalt, iridium, osmium, palladium, platinum, rhodium, ruthenium, molybdenum, and alloys thereof, most preferably of cobalt.

An electrolytic bath is prepared comprising copper ions and at least one additive according to the invention. A dielectric substrate having the seed layer is placed into the electrolytic bath where the electrolytic bath contacts the at least one outer surface and the three dimensional pattern having a seed layer in the case of a dielectric substrate. A counter electrode is placed into the electrolytic bath and an electrical current is passed through the electrolytic bath between the seed layer on the substrate and the counter electrode. At least a portion of copper is deposited into at least a portion of the three dimensional pattern wherein the deposited copper is substantially void-free.

The present invention is useful for depositing a layer comprising copper on a variety of substrates, particularly those having nanometer and variously sized apertures. For example, the present invention is particularly suitable for depositing copper on integrated circuit substrates, such as semiconductor devices, with small diameter vias, trenches or other recessed features. In one embodiment, semiconductor devices are plated according to the present invention. Such semiconductor devices include, but are not limited to, wafers used in the manufacture of integrated circuits.

In order to allow a deposition on a substrate comprising a dielectric surface a seed layer needs to be applied to the surface. Such seed layer may consist of cobalt, iridium, osmium, palladium, platinum, rhodium, and ruthenium or alloys comprising such metals. Preferred is the deposition on a cobalt seed. The seed layers are described in detail e.g. in US20140183738 A.

The underlying seed layer may be deposited or grown by chemical vapor deposition (CVD), atomic layer deposition (ALD), physical vapor deposition (PVD), electroplating, electro less plating or other suitable process that deposits conformal thin films. In an embodiment, the cobalt seed layer is deposited to form a high quality conformal layer that sufficiently and evenly covers all exposed surfaces within the openings and top surfaces. The high quality seed layer may be formed, in one embodiment, by depositing the cobalt seed material at a slow deposition rate to evenly and consistently deposit the conformal seed layer. By forming the seed layer in a conformal manner, compatibility of a subsequently formed fill material with the underlying structure may be improved. Specifically, the seed layer can assist a deposition process by providing appropriate surface energetics for deposition thereon.

In one embodiment the substrate comprises submicrometer sized features and the copper deposition is performed to fill the submicrometer sized features. Most preferably the submicrometer-sized features have an (effective) aperture size of 10 nm or below and/or an aspect ratio of 4 or more. More preferably the features have an aperture size of 7 nanometers or below, most preferably of 5 nanometers or below. Preferably the features bear a cobalt seed layer on which copper is electrodeposited.

In another embodiment a seed of copper is deposited onto the seeded surface of the substrate. Preferably this substrate comprises recessed features having an aperture size of 50 nm or below and/or an aspect ratio of 4 or more. Preferably the substrate bears a cobalt seed layer on which the copper seed layer is electrodeposited.

As used herein, “seed of copper” means a continuous thin layer of copper having a thickness of about 5 nm to about 15 nm.

The aperture size according to the present invention means the smallest diameter or free distance of a feature before plating, i.e. after seed deposition. The terms “aperture” and “opening” are used herein synonymously.

The electrodeposition current density should be chosen to promote the void-free filling behavior. A range of 0.1 to 40 mA/cm² is useful for this purpose. In a particular example, the current density can range from 1 to 10 mA/cm². In another particular example, the current density can range from 0.5 to 5 mA/cm².

Typically, substrates are electroplated by contacting the substrate with the plating baths of the present invention. The substrate typically functions as the cathode. The plating bath contains an anode, which may be soluble or insoluble. Optionally, cathode and anode may be separated by a membrane. Potential is typically applied to the cathode. Sufficient current density is applied and plating performed for a period of time sufficient to deposit a metal layer, such as a copper layer, having a desired thickness on the substrate. Suitable current densities include, but are not limited to, the range of 1 to 250 mA/cm². Typically, the current density is in the range of 1 to 60 mA/cm² when used to deposit copper in the manufacture of integrated circuits. The specific current density depends on the substrate to be plated, the agents and additives selected and the like. Such current density choice is within the abilities of those skilled in the art. The applied current may be a direct current (DC), a pulse current (PC), a pulse reverse current (PRC) or other suitable current. Typical temperatures used for the copper electroplating are from 10° C. to 50° C., preferably 20° C. to 40° C., most preferably from 20° C. to 35° C.

In general, when the present invention is used to deposit metal on a substrate such as a wafer used in the manufacture of an integrated circuit, the plating baths are agitated during use. Any suitable agitation method may be used with the present invention and such methods are well-known in the art. Suitable agitation methods include, but are not limited to, inert gas or air sparging, work piece agitation, impingement and the like. Such methods are known to those skilled in the art. When the present invention is used to plate an integrated circuit substrate, such as a wafer, the wafer may be rotated such as from 1 to 300 RPM and the plating solution contacts the rotating wafer, such as by pumping or spraying. In the alternative, the wafer need not be rotated where the flow of the plating bath is sufficient to provide the desired metal deposit.

Copper is deposited in recessed features according to the present invention without substantially forming voids within the metal deposit.

As used herein, void-free fill may either be ensured by an extraordinarily pronounced bottom-up copper growth while perfectly suppressing the sidewall copper growth, both leading to a flat growth front and thus providing substantially defect free trench/via fill (so-called bottom-up-fill) or may be ensured by a so-called V-shaped filling.

As used herein, the term “substantially void-free”, means that at least 95% of the plated apertures are void-free. Preferably that at least 98% of the plated apertures are void-free, mostly preferably all plated apertures are void-free. As used herein, the term “substantially seam-free”, means that at least 95% of the plated apertures are seam-free. Preferably that at least 98% of the plated apertures are seam-free, mostly preferably all plated apertures are seam-free.

Plating equipment for plating semiconductor substrates are well known. Plating equipment comprises an electroplating tank which holds Cu electrolyte and which is made of a suitable material such as plastic or other material inert to the electrolytic plating solution. The tank may be cylindrical, especially for wafer plating. A cathode is horizontally disposed at the upper part of tank and may be any type substrate such as a silicon wafer having openings such as trenches and vias.

The wafer substrate is typically coated with a seed layer of Cu or other metal or a metal containing layer to initiate plating thereon. An anode is also preferably circular for wafer plating and is horizontally disposed at the lower part of tank forming a space between the anode and cathode. The anode is typically a soluble anode.

These bath additives are useful in combination with membrane technology being developed by various tool manufacturers. In this system, the anode may be isolated from the organic bath additives by a membrane. The purpose of the separation of the anode and the organic bath additives is to minimize the oxidation of the organic bath additives.

The cathode substrate and anode are electrically connected by wiring and, respectively, to a rectifier (power supply). The cathode substrate for direct or pulse current has a net negative charge so that Cu ions in the solution are reduced at the cathode substrate forming plated Cu metal on the cathode surface. An oxidation reaction takes place at the anode. The cathode and anode may be horizontally or vertically disposed in the tank.

While the process of the present invention has been generally described with reference to semiconductor manufacture, it will be appreciated that the present invention may be useful in any electrolytic process where a substantially void-free copper deposit is desired. Such processes include printed wiring board manufacture. For example, the present plating baths may be useful for the plating of vias, pads or traces on a printed wiring board, as well as for bump plating on wafers. Other suitable processes include packaging and interconnect manufacture. Accordingly, suitable substrates include lead frames, interconnects, printed wiring boards, and the like.

All percent, ppm or comparable values refer to the weight with respect to the total weight of the respective composition except where otherwise indicated. All cited documents are incorporated herein by reference.

The following examples shall further illustrate the present invention without restricting the scope of this invention.

### EXAMPLES

3-Carboxy-1-penylmethylpyridinium (inner salt with Na⁺ and Cl⁻) used in the examples is available from BASF SE.

### Example 1a: Synthesis of Defect Reducing Agent 1

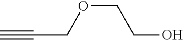

Propargyl alcohol (280.3 g) and triphenylphosphine (2.0 g) were placed into a 3.5 l autoclave. After nitrogen neutralization, the pressure was adjusted to 1.5 bar and the mixture was homogenized at 60° C. for 1 h. Then ethylene oxide (220.3 g) was added at 60° C. over a period of 4 h, reaching a maximum pressure of 3.5 bar. The reaction mixture was then heated up over 30 min to 80° C., reaching a maximum pressure of 4 bar. To complete the reaction, the mixture post-react for 6 h at 80° C. Then, the temperature was decreased to 40° C. Volatile compounds were re-moved in vacuum at 60° C. Defect Reducing agent 1 was obtained as yellowish liquid (494.4 g), having a hydroxy value of 569 mg/g.

### Example 1b: Synthesis of Defect Reducing Agent 2

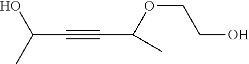

3-Hexin-2,5-diol (456.6 g) and Imidazol (2.5 g) were placed into a 3.5 l autoclave. After nitrogen neutralization, the pressure was adjusted to 1.0 bar and the mixture was homogenized at 70° C. for 1 h. Then ethylene oxide (176.2 g) was added at 70° C. over a period of 1 h, reaching a maximum pressure of 3.5 bar. To complete the reaction, the mixture post-react for 6 h at 70° C. Then, the temperature was decreased to 60° C. Volatile compounds were removed in vacuum at 60° C. Defect Reducing agent 2 was obtained as orange liquid (630.8 g), having a hydroxy value of 709 mg/g.

### Example 1c: Synthesis of Defect Reducing Agent 3

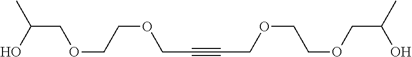 [SMILES: CC(O)COCCOCC#CCOCCOCC(C)O]

2-Methyl-3-butin-2-ol (420.6 g) and Imidazol (3.4 g) were placed into a 3.5 l autoclave. After nitrogen neutralization, the pressure was adjusted to 1.5 bar and the mixture was homogenized at 70° C. for 1 h. Then ethylene oxide (440.5 g) was added at 70° C. over a period of 8 h, reaching a maximum pressure of 3.5 bar. To complete the reaction, the mixture post-react for 6 h at 70° C. Then, the temperature was decreased to 60° C. Volatile compounds were removed in vacuum at 60° C. Intermediate 1 (=2-Methyl-3-butin-2-ol+2 EO) was obtained as orange liquid (835.3 g), having a hydroxy value of 325 mg/g.

Intermediate 1 (300 g) and Imidazol (0.7 g) were placed into a 3.5 l autoclave. After nitrogen neutralization, the pressure was adjusted to 2.2 bar and the mixture was homogenized at 70° C. for 1 h. Then propylene oxide (202.4 g) was added at 70° C. over a period of 7 h, reaching a maximum pressure of 3.2 bar. To complete the reaction, the mixture post-react for 6 h at 70° C. Then, the temperature was decreased to 60° C. Volatile compounds were removed in vacuum at 60° C. Defect Reducing agent 3 was obtained as dark orange liquid (488.5 g).

### Example 1d: Synthesis of Defect Reducing Agent 4

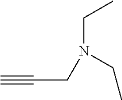

The reaction was done in a 2 l 4-neck flask equipped with a stirrer, condenser tube, thermometer, and nitrogen inlet pipe. Diethylamin (240 g) and water (324 g) were placed into the flask and heated up to 40° C. Then Protectol KCL (1.3 g) was added and propargylchlorid (342.3 g) was added over 2 h and 50 min, reaching a maximum temperature of 56° C. The reaction mixture was then stirred for 3.5 h at 50° C. Over this time the pH value was adjusted >10 with sodium hydroxid (50%). The mixture was placed in a separating funnel. The water phase was separated. The organic phase was added with water (100 g) and the pH was adjusted to 3.5 with hydrochloric acid (222 g). The lower aqueous phase was separated; the organic phase was discarded. The water phase, that contains the product as hydrochloride form was adjusted with 50% NaOH (186.8 g) to pH=9.5-10. The Product was released as organic phase and the water phase was discarded. For further purification the product was distilled at 50° C. internal temperature and 35 mbar. The product was obtained as colorless liquid (175 g).

1H-NMR (400 MHz, D2O): δ(ppm)=1.25 (6H, —CH3), 2.54 (4H, —CH2), 3.41 (2H, —CH2), 4.8 (1H, CH).

### Copper Electroplating Experiments

For some plating experiments a blanket wafer substrate was used bearing a 100 A CVD Co seed on a 30 A TaN layer.

For some plating experiments a patterned wafer substrate was used as shown in FIG. 1. The wafer substrate was bearing a 100 A Co seed on a 30 A TaN layer and having features with a diameter of 24 nm at the top of the opening, a diameter of 20 nm at half height of the feature. The feature height was about 105 nm which results in an aspect ratio of about 5.25.

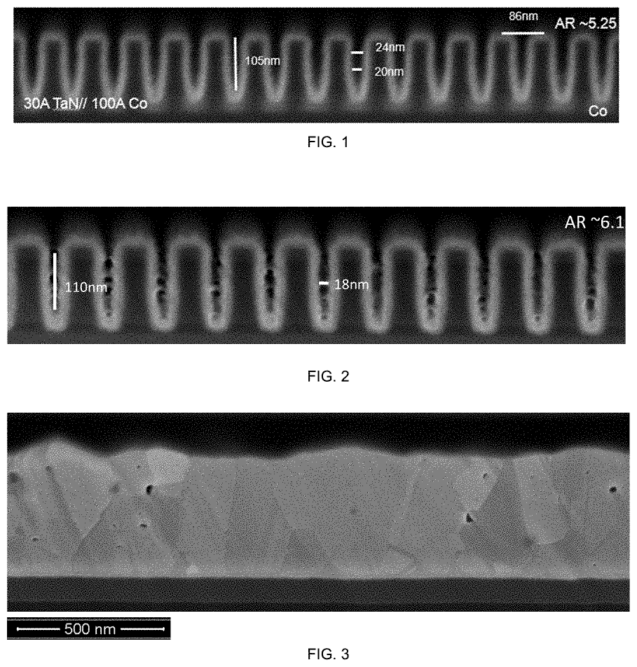

For some plating experiments a patterned wafer substrate was used as shown in FIG. 2. The wafer substrate was bearing a 50 A Co seed on a 30 A TaN layer and having features with a diameter of 18 nm at half height of the feature. The feature height was about 110 nm which results in an aspect ratio of about 6.

### Example 2: Cu Electrodeposition with Defect Reducing Agent

### Comparative Example 2a

A plating bath was prepared by combining DI water, 0.5 g/l copper as copper sulfate, citric acid in a molar ratio of 2:1 to Cu, and a solution of sodium hydroxide or potassium hydroxide to adjust a pH of 9. A copper layer was electroplated onto a blanket wafer substrate bearing a cobalt seed layer by contacting the wafer substrate with the above described plating bath at 25° C. applying a direct current of −2.0 mA/cm² for 2000 s. The thus electroplated copper layer was annealed at 400° C. for 5 minutes in forming gas and was investigated by FIB/SEM inspection.

The result is shown in FIG. 3 which provides the SEM image of the electroplated copper film. FIG. 3 shows that the electroplated copper exhibits defects like holes and voids.

### Example 2b

The experiment as described in Example 2a was repeated with addition of 1 ml/l of a solution in DI water of 0.9 wt % of defect reducing agent 1 to the plating bath.

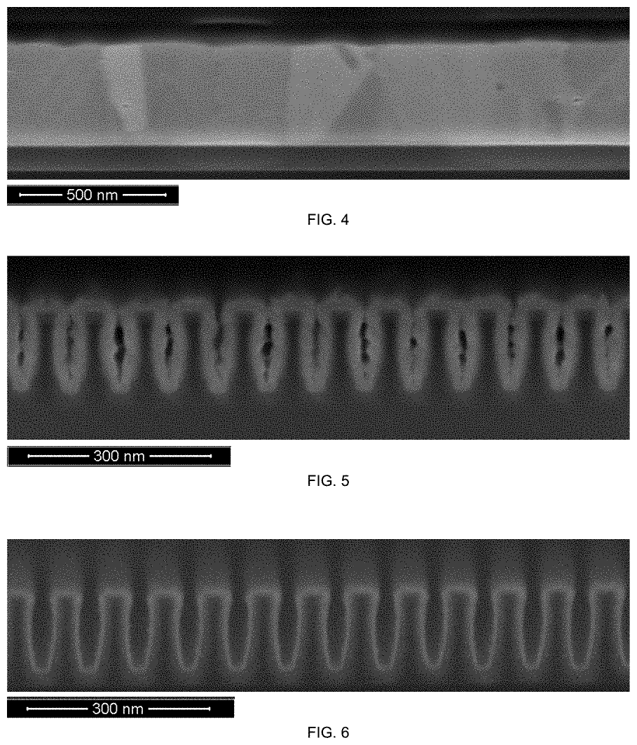

The result is shown in FIG. 4 which provides the SEM image of the electroplated copper film. FIG. 4 shows significantly less defects in the electroplated copper film.

### Comparative Example 2c

A plating bath was prepared by combining DI water, 0.5 g/l copper as copper sulfate, citric acid in a molar ratio of 2:1 to Cu, and a solution of sodium hydroxide or potassium hydroxide to adjust a pH of 9. A copper layer was electroplated onto a patterned wafer substrate as shown in FIG. 1 by contacting the wafer substrate with the above described plating bath at 25° C. applying a direct current of −2.0 mA/cm² for 125 s. The thus electroplated copper layer was investigated by FIB/SEM inspection.

The result is shown in FIG. 5 which provides the SEM image of the electroplated copper film. FIG. 5 shows a conformal Cu deposition inside the features exhibiting a rough and uneven Cu surface.

### Example 2d

The experiment as described in Example 2c was repeated with addition of 25 ml/l of a solution in DI water of 0.9 wt % of defect reducing agent 1 to the plating bath.

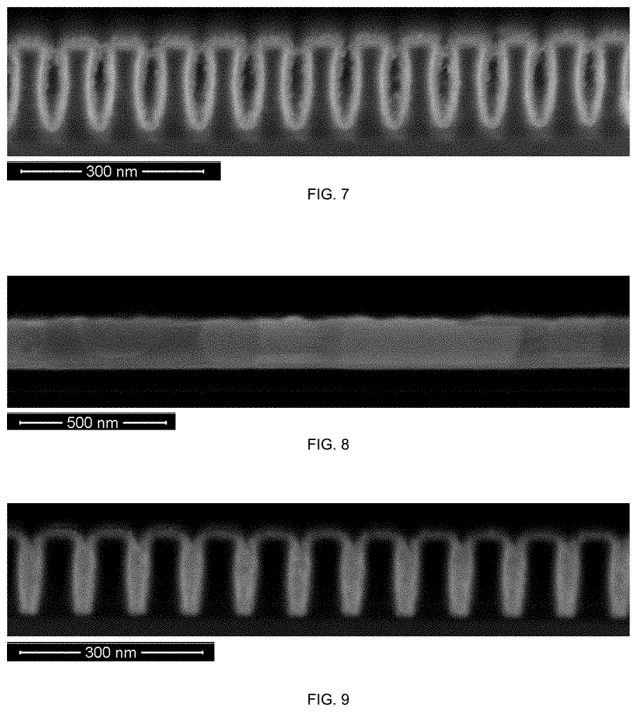

The result is shown in FIG. 6 which provides the SEM image of the electroplated copper film. FIG. 6 shows a continuous and smooth metal film inside the features.

### Example 2e

The experiment as described in Example 2c was repeated with addition of 10 ml/L of a solution in DI water of 0.9 wt % of defect reducing agent 4 to the plating bath.

The result is shown in FIG. 7 which provides the SEM image of the electroplated copper film. FIG. 7 shows a conformal Cu deposition inside the features. The surface of the deposited Cu is less rough as without additive shown in FIG. 5.

### Example 3: Cu Electrodeposition with Defect Reducing Agent and Grain Refiner

3-Carboxy-1-penylmethylpyridinium was used as grain refiner in combination with a defect reducing agent in alkaline Cu electroplating baths. The grain refiner helps to reduce the roughness of the electrodeposited copper layer and thus also prevents the formation of defects in the electrodeposited Cu film.

### Example 3a

A plating bath was prepared by combining DI water, 0.5 g/l copper as copper sulfate, citric acid in a molar ratio of 2:1 to Cu, and a solution of sodium hydroxide or potassium hydroxide to adjust a pH of 9. 10 ml/l of a solution in DI water of 0.9 wt % of defect reducing agent 1 and 0.5 ml/l of a solution in DI water of 0.9 wt % 3-Carboxy-1-penylmethylpyridinium were added to the electrolyte. A copper layer was electroplated onto a blanket wafer substrate bearing a cobalt seed layer by contacting the wafer substrate with the above described plating bath at 25° C. applying a direct current of −2.0 mA/cm² for 1000 s. The thus electroplated copper layer was annealed at 400° C. for 5 minutes in forming gas and was investigated by FIB/SEM inspection.

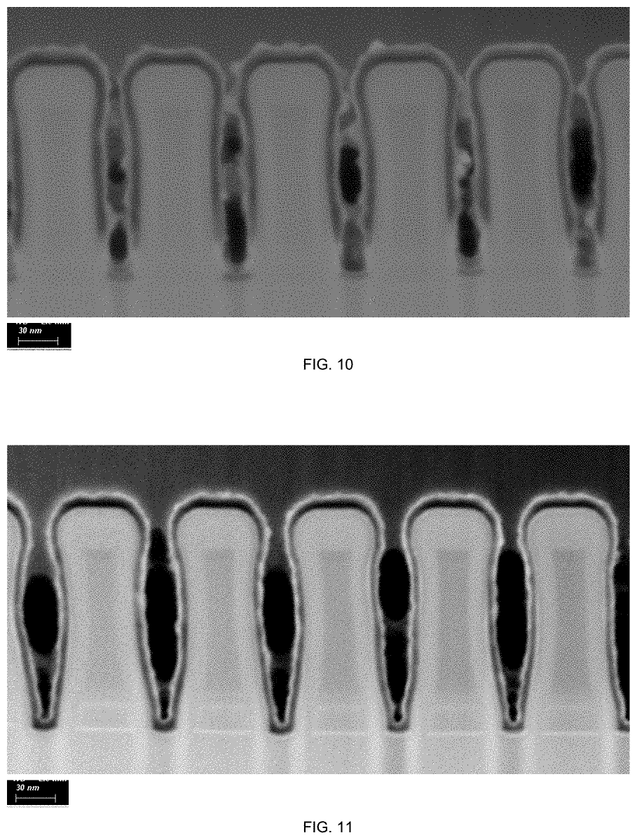

The result is shown in FIG. 8 which provides the SEM image of the electroplated copper film. FIG. 8 shows that the electroplated copper film is mainly free of defects.

### Example 3b

A plating bath was prepared by combining DI water, 0.5 g/l copper as copper sulfate, citric acid in a molar ratio of 2:1 to Cu, and a solution of sodium hydroxide or potassium hydroxide to adjust a pH of 9. 10 ml/l of a solution in DI water of 0.9 wt % of defect reducing agent 1 and 1.0 ml/l of a solution in DI water of 0.9 wt % 3-Carboxy-1-penylmethylpyridinium were added to the electrolyte. A copper layer was electroplated onto a patterned wafer substrate as shown in FIG. 2 by contacting the wafer substrate with the above described plating bath at 25° C. applying a direct current of −1.0 mA/cm² for 250 s. The thus electroplated copper layer was investigated by FIB/SEM inspection.

The result is shown in FIG. 9 which provides the SEM image of the features filled with Cu. FIG. 9 shows that the electroplated copper film is mainly free of defects.

### Comparative Example 3c

A plating bath was prepared by combining DI water, 0.5 g/l copper as copper sulfate, citric acid in a molar ratio of 2:1 to Cu, and a solution of sodium hydroxide or potassium hydroxide to adjust a pH of 9. A copper layer was electroplated onto a patterned wafer substrate as shown in FIG. 2 by contacting the wafer substrate with the above described plating bath at 22° C. applying a direct current of −1.0 mA/cm² for 50 s. The thus electroplated copper layer was investigated by FIB/SEM inspection.

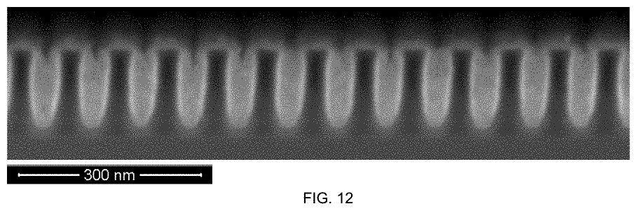

The result is shown in FIG. 10 which provides the SEM image of the electroplated copper film. FIG. 10 shows a nonconformal and rough metal film inside the features.

### Example 3d

The experiment as described in Example 3c was repeated with addition of 10 ml/l of a solution in DI water of 0.9 wt % of defect reducing agent 2 and 1.0 ml/l of a solution in DI water of 0.9 wt % 3-Carboxy-1-penylmethylpyridinium to the plating bath.

A copper layer was electroplated onto a patterned wafer substrate as shown in FIG. 2 by contacting the wafer substrate with the above described plating bath at 22° C. applying a direct current of −1.0 mA/cm² for 100 s. The thus electroplated copper layer was investigated by FIB/SEM inspection.

The result is shown in FIG. 11 which provides the SEM image of the electroplated copper film. FIG. 11 shows a continuous and smooth metal film inside the features.

### Example 3e

A plating bath was prepared by combining DI water, 0.5 g/l copper as copper sulfate, citric acid in a molar ratio of 2:1 to Cu, and a solution of sodium hydroxide or potassium hydroxide to adjust a pH of 9. 10 ml/L of a solution in DI water of 0.9 wt % of defect reducing agent 3 and 1.0 ml/l of a solution in DI water of 0.9 wt % 3-Carboxy-1-penylmethylpyridinium were added to the plating bath.

A copper layer was electroplated onto a patterned wafer substrate as shown in FIG. 1 by contacting the wafer substrate with the above described plating bath at 25° C. applying a direct current of −1.0 mA/cm² for 250 s. The thus electroplated copper layer was investigated by FIB/SEM inspection.

The result is shown in FIG. 12 which provides the SEM image of the features filled with Cu. FIG. 12 shows that the features are mainly free of defects.

1. A composition for depositing copper on a semiconductor substrate, the composition comprising
(a) copper ions;
(b) a defect reducing agent of formula S1 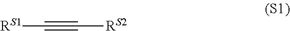
(c) a complexing agent; and
(d) optionally a buffer or a base capable of adjusting the pH to a pH of from 7 to 13;
wherein
R^{S1} is selected from the group consisting of X^{S}—Y^{S};
R^{S2} is selected from the group consisting of R^{S1} and R^{S3};
X^{S} is selected from the group consisting of linear or branched C₁ to C₁₀ alkanediyl, linear or branched C₂ to C₁₀ alkenediyl, linear or branched C₂ to C₁₀ alkynediyl, and —X^{S6}—(O—C₂H₃R^{S6})ₘ—;
Y^{S} is selected from the group consisting of OR^{S3}, NR^{S3}R^{S4} N+R^{S3}R^{S4}R^{S5} and NH—(C═O)—R^{S3};
R^{S3}, R^{S4}, R^{S5} are the same or different and are selected from the group consisting of (i) H, (ii) C₅ to C₂₀ aryl, (iii) C₁ to C₁₀ alkyl (iv) C₆ to C₂₀ arylalkyl, (v) C₆ to C₂₀ alkylaryl, which may be substituted by OH, SO₃H, COOH or a combination thereof, and
(vi) —(C₂H₃R^{S6}—O)ₙ—R^{S6}, and wherein R^{S3} and R^{S4} may together form a ring system, which may be interrupted by O or NR^{S7};
X^{S6} is C₁ to C₆ alkanediyl;
m, n are integers independently selected from the group consisting of 1 to 30;
R^{S6} is selected from the group consisting of H and C₁ to C_{S} alkyl;
R^{S7} is selected from the group consisting of R^{S6} and 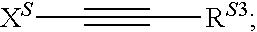
and
wherein a pH of the composition is from 7 to 13 and wherein the composition is free of any cyanide ions.

2. The composition according to claim 1, wherein X^{S} is selected from the group consisting of C₁ to C₆ alkanediyl.

3. The composition according to claim 1, wherein X^{S} is selected from the group consisting of propan-1,1-diyl, butane-1,1-diyl, pentane-1,1-diyl, hexane-1,1-diyl, propane-2-2-diyl, butane-2,2-diyl, pentane-2,2-diyl, and hexane-2,2-diyl or is selected from the group consisting of propane-1-2-diyl, butane-1,2-diyl, pentane-1,2-diyl, hexane-1,2-diyl, propane-1-3-diyl, butane-1,3-diyl, pentane-1,3-diyl, and hexane-1,3-diyl.

4. The composition according to claim 1, wherein R^{S2} is H.

5. The composition according to claim 1, wherein Y^{S} is OR^{S3} and R^{S3} is H.

6. The composition according to claim 1, wherein Y^{S} is OR^{S3} and R^{S3} is selected from the group consisting of a polyoxyalkylene group of formula —(C₂H₃R^{S6}—O)ₙ—R^{S6}.

7. The composition according to claim 1, wherein Y^{S} is NR^{S3}R^{S4} and R^{S3} and R^{S4} are independently selected from the group consisting of H, methyl and ethyl.

8. The composition according to claim 1, wherein Y^{S} is NR^{S3}R^{S4} and wherein R^{S3} and R^{S4} are H, or one of R^{S3} and R^{S4} is H.

9. The composition according to claim 1, wherein Y^{S} is NR^{S3}R^{S4} and at least one of R^{S3} and R^{S4} are selected from the group consisting of polyoxyalkylene groups of formula —(C₂H₃R^{S6}—O)ₙ—R^{S6}.

10. The composition according to claim 1, wherein Y^{S} is N⁺R^{S3}R^{S4}R^{S5} and R^{S3}, R^{S4} and R^{S5} are independently selected from the group consisting of H, methyl and ethyl.

11. The composition according to claim 1, wherein Y^{S} is N⁺R^{S3}R^{S4}R^{S5} and at least one of R^{S3} and R^{S4} are selected from the group consisting of polyoxyalkylene groups of formula —(C₂H₃R^{S6}—O)ₙ—R^{S6}.

12. The composition according to claim 1, which further comprises a grain refiner of formula G1 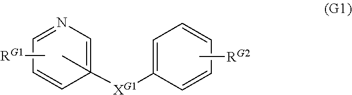
or salts thereof,
wherein
R^{G1} is selected from the group consisting of one or more H, C₁ to C₄ carboxyl, C₁ to C₄ alkyl, C₁ to C₆ alkoxy, halogen, and CN;
R^{G2} is selected from the group consisting of one or more H, C₁ to C₄ carboxyl, C₁ to C₄ alkyl, C₁ to C₆ alkoxy, halogen, and CN; and
X^{G1} is selected from the group consisting of C₁ to C₆ alkanediyl and a group —X^{G11}—C(O)—O—X^{G12}—;
X^{G11} is selected from the group consisting of a chemical bond and C₁ to C₄ alkandiyl;
X^{G12} is selected from the group consisting of a chemical bond and C₁ to C₄ alkandiyl; and
wherein R^{G1} or R^{G2}, comprises at least one C₁ to C₄ carboxyl group, or group X^{G1} is —X^{G11}—C(O)—O—)—X^{G12}—.

13. A method of using a composition according to claim 1, the method comprising using the composition for depositing copper on a semiconductor substrate comprising recessed features having an aperture size 50 nanometers or less.

14. A process for depositing copper on a semiconductor substrate comprising a recessed feature having an aperture size of 50 nm or less, the recessed feature comprising a metal seed, the process comprising
(a) bringing a composition according to claim 1 into contact with the metal seed, and
(b) applying a current for a time sufficient to deposit a continuous seed of copper onto the metal seed of the recessed feature or to completely fill the recessed feature.

15. The process according to claim 14, wherein the seed layer consists of cobalt, iridium, osmium, palladium, platinum, rhodium, ruthenium, molybdenum, and alloys thereof.

16. The composition according to claim 1, wherein X^{S} is selected from the group consisting of methanediyl and 1,1 or 1,2 ethanediyl.

17. The composition according to claim 1, wherein Y^{S} is NR^{S3}R^{S4} and both of R^{S3} and R^{S4} are selected from the group consisting of polyoxyalkylene groups of formula —(C₂H₃R^{S6}—O)ₙ—R^{S6}.

18. The composition according to claim 1, wherein Y^{S} is N⁺R^{S3}R^{S4}R^{S5} and at least two of R^{S3} and R^{S4} are selected from the group consisting of polyoxyalkylene groups of formula —(C₂H₃R^{S6}—O)ₙ—R^{S6}.

19. The method of use according to claim 13, wherein the recessed features have an aperture size of 15 nm or less.

20. The process according to claim 14, wherein the recessed feature has an aperture size of 15 nm or less.
